(19) United States
(12) Patent Application Publication
(10) Pub. No.: US 2023/0030470 A1
(43) Pub. Date: Feb. 2, 2023

(54) SUBSTRATE SUPPORTING APPARATUS AND SUBSTRATE PROCESSING APPARATUS

(71) Applicant: Kioxia Corporation, Tokyo (JP)

(72) Inventor: Ryo SHINOZAKI, Yokkaichi Mie (JP)

(73) Assignee: Kioxia Corporation, Tokyo (JP)

(21) Appl. No.: 17/545,144

(22) Filed: Dec. 8, 2021

(30) Foreign Application Priority Data
Jul. 27, 2021 (JP) 2021-122404

(51) Int. Cl. H01L 21/683; H01L 21/687

(52) U.S. Cl. CPC H01L 21/6833; H01L 21/68742

(57) ABSTRACT

According to one embodiment, a substrate supporting apparatus includes a mounting plate that is configured by including ceramics and has a mounting surface on which the substrate is to be mounted; a power supply plate that is built in the mounting plate and electrostatically attracts the substrate to the mounting plate; a plurality of protruding portions which internally includes an electrically conductive member respectively, is arranged on at least a central region and outer edge region of the mounting plate, and protrudes from the mounting surface; and a plurality of elastic members which is embedded in the mounting plate to correspond to the plurality of protruding portions, supports the plurality of protruding portions while protruding the protruding portions from the mounting surface, and electrically connects the power supply plate and the electrically conductive members included in the plurality of protruding portions to each other.

### CROSS-REFERENCE TO RELATED APPLICATIONS

This application is based upon and claims the benefit of priority from Japanese Patent Application No. 2021-122404, filed on Jul. 27, 2021; the entire contents of which are incorporated herein by reference.

### FIELD

Embodiments described herein relate generally to a substrate supporting apparatus and a substrate processing apparatus.

### BACKGROUND

In a substrate processing apparatus, a substrate supporting apparatus is sometimes used, which supports a substrate in a processing container by electrostatically attracting the substrate or by sucking and attracting the substrate. However, if the substrate is warped, then the substrate is sometimes damaged by receiving a shock at the time of being attracted to the substrate supporting apparatus.

### BRIEF DESCRIPTION OF THE DRAWINGS

FIG. 1 is a cross-sectional view schematically illustrating an example of a configuration of a plasma processing apparatus according to a first embodiment;

FIG. 2 is a top view of an electrostatic chuck according to the first embodiment;

FIG. 3 is a view illustrating a cross-sectional structure of the electrostatic chuck according to the first embodiment;

FIGS. 4A to 4C are cross-sectional views illustrating an example of a procedure of plasma processing in the plasma processing apparatus according to the first embodiment;

FIGS. 5A to 5E are cross-sectional views illustrating an example of a procedure of the plasma processing in the plasma processing apparatus according to the first embodiment and processing subsequent to the plasma processing;

FIGS. 6A and 6B are cross-sectional views illustrating an example of a procedure of preheating in a plasma processing apparatus according to a comparative example;

FIG. 7 is a view illustrating a cross-sectional structure of an electrostatic chuck provided in a plasma processing apparatus according to a first modified example of the first embodiment;

FIG. 8 is a view illustrating a cross-sectional structure of an electrostatic chuck provided in a plasma processing apparatus according to a second modified example of the first embodiment;

FIG. 9 is a top view of an electrostatic chuck provided in a plasma processing apparatus according to a third modified example of the first embodiment;

FIG. 10 is a top view of an electrostatic chuck provided in a plasma processing apparatus according to a fourth modified example of the first embodiment;

FIG. 11 is a diagram schematically illustrating an example of a configuration of an exposure processing apparatus according to a second embodiment; and

FIG. 12 is a view illustrating a cross-sectional structure of a wafer chuck according to the second embodiment.

### DETAILED DESCRIPTION

A substrate supporting apparatus of an embodiment is a substrate supporting apparatus that supports a substrate in a processing container of a substrate processing apparatus, the substrate supporting apparatus including: a mounting plate that is configured by including ceramics and has a mounting surface on which the substrate is to be mounted; a power supply plate that is built in the mounting plate and electrostatically attracts the substrate to the mounting plate; a plurality of protruding portions which internally includes an electrically conductive member respectively, is arranged on at least a central region and outer edge region of the mounting plate, and protrudes from the mounting surface; and a plurality of elastic members which is embedded in the mounting plate to correspond to the plurality of protruding portions, supports the plurality of protruding portions while protruding the protruding portions from the mounting surface, and electrically connects the power supply plate and the electrically conductive members included in the plurality of protruding portions to each other.

The present invention will be described below in detail with reference to the drawings. Note that the present invention is not limited to the following embodiments. Further, components in the following embodiments include those which can be easily conceived by those skilled in the art or substantially the same ones as such.

### First Embodiment

A first embodiment will be described below in detail with reference to the drawings.

(Configuration Example of Plasma Processing Apparatus)

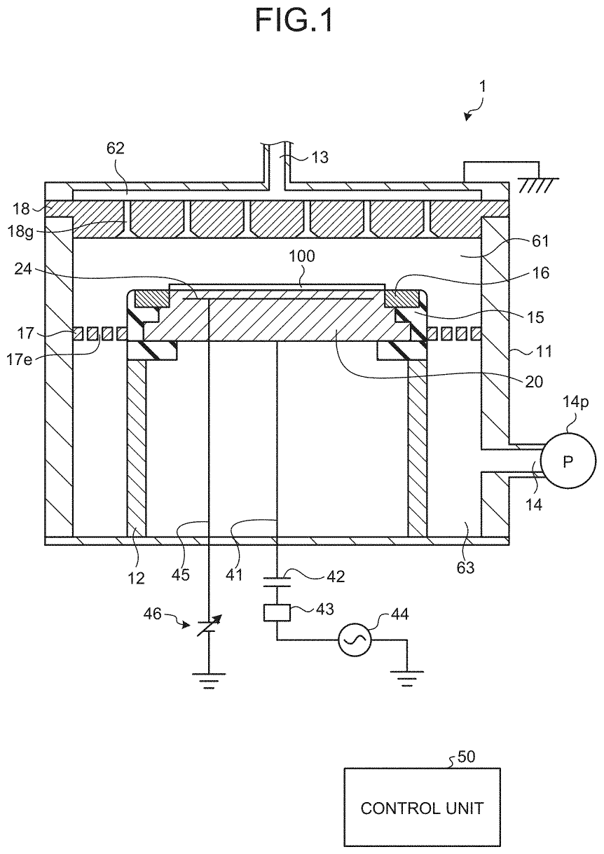

FIG. 1 is a cross-sectional view schematically illustrating an example of a configuration of a plasma processing apparatus 1 according to the first embodiment. For example, the plasma processing apparatus 1 is configured as a chemical vapor deposition (CVD) apparatus that forms a predetermined film on a wafer 100.

As illustrated in FIG. 1, the plasma processing apparatus 1 as a substrate processing apparatus includes a chamber 11 as a processing container for processing the wafer 100. The chamber 11 is made of aluminum for example, and is hermetically sealable.

A gas supply port 13 is provided in an upper portion of the chamber 11. A gas supply apparatus (not illustrated) is connected to the gas supply port 13 through a pipe, and is supplied with processing gas for use in processing the wafer 100.

Below the gas supply port 13, a shower head 18 that functions as an upper electrode is provided. The shower head 18 is provided with a plurality of gas outlet ports 18g which penetrate the shower head 18 in a plate thickness direction. The processing gas supplied from the gas supply port 13 is introduced into the chamber 11 through the gas outlet ports 18g. Below the shower head 18, an electrostatic chuck 20 is disposed so as to face the shower head 18.

The electrostatic chuck 20 as a substrate supporting apparatus horizontally supports the wafer 100 as a processing target in the chamber 11, electrostatically attracts the wafer 100, and also functions as a lower electrode. In a side surface of the chamber 11, a loading/unloading port (not illustrated) for the wafer 100 is provided, and the wafer 100 is mounted on the electrostatic chuck 20 in the chamber 11 by a carrying arm (not illustrated) from this loading/unloading port.

The electrostatic chuck 20 is supported on a support portion 12 that protrudes in a cylindrical shape vertically upward from a bottom wall near the center of the chamber 11. The support portion 12 supports the electrostatic chuck 20 near the center of the chamber 11 at a predetermined distance from the shower head 18 so as to face the shower head 18 in parallel. With such a structure, the shower head 18 and the electrostatic chuck 20 constitute a pair of planar electrodes parallel to each other.

Further, the electrostatic chuck 20 includes a chuck mechanism that electrostatically attracts the wafer 100. The chuck mechanism includes a chuck electrode 24 as a power supply plate, a power supply line 45, and a power supply 46 as a first power supply. The power supply 46 is connected to the chuck electrode 24 via the power supply line 45. With such a mechanism, direct-current power is supplied from the power supply 46 to the chuck electrode 24, and an upper surface of the electrostatic chuck 20 is electrostatically charged. Other internal configurations of the electrostatic chuck 20 will be described later.

A power supply line 41 is connected to the electrostatic chuck 20. A blocking capacitor 42, a matching unit 43, and a high-frequency power supply 44 are connected to the power supply line 41. At the time of plasma processing, high-frequency power with a predetermined frequency is supplied from the high-frequency power supply 44 to the electrostatic chuck 20. With such a mechanism, the electrostatic chuck 20 also functions as a lower electrode.

On an outer circumference of the electrostatic chuck 20, an insulator ring 15 is disposed so as to cover a side surface of the electrostatic chuck 20 and a circumferential edge portion of a bottom surface thereof. On the insulator ring 15, an outer circumferential ring 16 is provided so as to surround the outer circumference of the electrostatic chuck 20. The outer circumferential ring 16 adjusts an electric field so that the electric field does not deflect with respect to a vertical direction, that is, a direction perpendicular to the surface of the wafer 100 on a circumferential edge portion of the wafer 100 at the time of etching the wafer 100.

A baffle plate 17 is provided between the insulator ring 15 and a side wall of the chamber 11. The baffle plate 17 has a plurality of gas discharge holes 17e which penetrate the baffle plate 17 in the plate thickness direction.

A gas discharge port 14 is provided on a portion of the chamber 11, which is below the baffle plate 17. A vacuum pump 14p that vacuums an atmosphere in the chamber 11 is connected to the gas discharge port 14.

A region partitioned by the shower head 18 and by the electrostatic chuck 20 and the baffle plate 17 in the chamber 11 serves as a plasma processing chamber 61. A region in the upper portion of the chamber 11, the region being partitioned by the shower head 18, serves as a gas supply chamber 62. A region in a lower portion in the chamber 11, the region being partitioned by the electrostatic chuck 20 and the baffle plate 17, serves as a gas discharge chamber 63.

The plasma processing apparatus 1 includes a control unit 50 that controls the respective units of the plasma processing apparatus 1, such as the power supply 46, the matching unit 43, the high-frequency power supply 44, and the gas supply apparatus. The control unit 50 is configured as a computer including a central processing unit (CPU), a read only memory (ROM), a random access memory (RAM), and the like, all of which are not illustrated. The control unit 50 may be configured as an application specific integrated circuit (ASIC) that has functions for applications of the plasma processing apparatus 1.

When the wafer 100 is subjected to the plasma processing, then in accordance with the control of the control unit 50, the wafer 100 as a processing target is mounted on the electrostatic chuck 20, and is attracted by the chuck mechanism. Further, the inside of the chamber 11 is evacuated by the vacuum pump 14p connected to the gas discharge port 14. When the inside of the chamber 11 reaches a predetermined pressure, the processing gas is supplied from the gas supply apparatus (not illustrated) to the gas supply chamber 62, and is supplied to the plasma processing chamber 61 via the gas outlet port 18g of the shower head 18.

Further, in accordance with the control of the control unit 50, a high-frequency voltage is applied to the electrostatic chuck 20 as a lower electrode in a state where the shower head 18 as an upper electrode is grounded, whereby plasma is generated in the plasma processing chamber 61. In the lower electrode, a potential gradient is generated between the plasma and the wafer 100 due to a self bias by the high-frequency voltage, and ions in the plasma are accelerated to the electrostatic chuck 20, and anisotropic etching is performed.

(Configuration Example of Electrostatic Chuck)

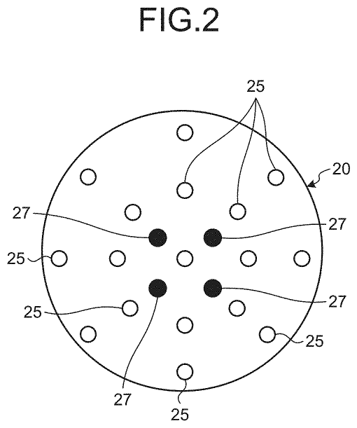

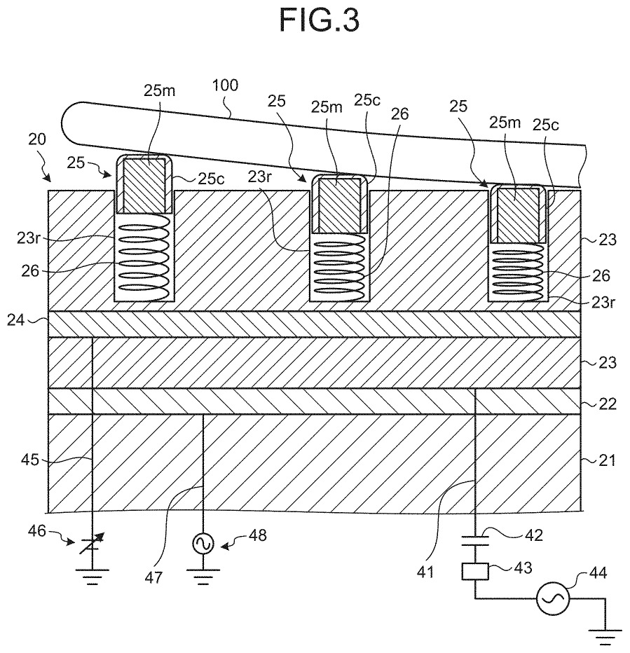

Next, a detailed configuration of the electrostatic chuck 20 will be described with reference to FIGS. 2 and 3.

FIG. 2 is a top view of the electrostatic chuck 20 according to the first embodiment. As illustrated in FIG. 2, the electrostatic chuck 20 includes, on the upper surface thereof, a plurality of lift pin housing holes 27 and a plurality of protruding portions 25.

The plurality of lift pin housing holes 27 are arranged, for example, on the central region of the upper surface of the electrostatic chuck 20 so as to be spaced apart from one another, and individually house lift pins (not illustrated) in the inside of the electrostatic chuck 20. At the time of carrying in/out the wafer 100 to/from the chamber 11, the lift pins are protruded from the upper surface of the electrostatic chuck 20, and the wafer 100 is supported on the lift pins, whereby the wafer 100 is delivered between the carrying arm (not illustrated) and the electrostatic chuck 20.

The plurality of protruding portions 25 protrude from the upper surface of the electrostatic chuck 20, and are arranged in a dispersed manner on the entire upper surface of the electrostatic chuck 20. More specifically, the plurality of protruding portions 25 are arranged, for example, radially from the central portion of the upper surface of the electrostatic chuck 20 toward an outer edge portion thereof.

The wafer 100 mounted on the upper surface of the electrostatic chuck 20 is supported substantially by the plurality of protruding portions 25. Thus, between the upper surface of the electrostatic chuck 20 and the wafer 100, a gap is generated by a protrusion amount of each of the protruding portions 25. In order to improve thermal conductivity between the electrostatic chuck 20 and the wafer 100, inert gas such as helium gas is flown into this gap.

Note that FIG. 2 is a simplified view, and with regard to the protruding portions 25, for example, 33 or more and 121 or less thereof can be arranged on the electrostatic chuck 20. The number of protruding portions 25 is set to, for example, 33 or more, whereby the weight of the wafer 100 can be dispersed among the plurality of protruding portions 25, and a shock when the protruding portions 25 and the wafer 100 abut against each other can be absorbed. When the number of protruding portions 25 exceeds 121 for example, an effect of absorbing the shock becomes substantially constant.

An upper surface shape of the plurality of protruding portions 25 is, for example, circular. The protruding portions 25 may have an elliptical or oval upper surface shape. Further, the upper surface shape of the protruding portions 25 can also be set polygonal and so on. However, more preferably, the protruding portions 25 have a rounded shape without corners in order to absorb the shock when the protruding portions 25 abut against the wafer 100.

FIG. 3 is a view illustrating a cross-sectional structure of the electrostatic chuck 20 according to the first embodiment. In FIG. 3, the vicinity of the outer edge portion of the electrostatic chuck 20 is enlargedly illustrated. As illustrated in FIG. 3, the electrostatic chuck 20 includes, as a cross-sectional structure, a base material 21, a heater 22, a ceramic plate 23, and the chuck electrode 24.

The base material 21 is a main body of the electrostatic chuck 20, and is made of aluminum for example. The base material 21 has a flat upper surface.

The heater 22 as an electric heating plate has a predetermined pattern, and is disposed on substantially the entire upper surface of the base material 21. The heater 22 constitutes a part of a heating mechanism that heats the wafer 100. That is, the heating mechanism includes the heater 22, a power supply line 47, and a power supply 48 as a second power supply. To the heater 22, the power supply 48 that supplies power to the heater 22 is connected via the power supply line 47.

By such a mechanism as described above, alternating-current power is supplied from the power supply 48 to the heater 22, and the heater 22 is heated. Thus, the wafer 100 mounted on the electrostatic chuck 20 is heated to a temperature, for example, of 650° C. or higher.

The ceramic plate 23 as a mounting plate is formed into a shape of a flat plate that covers substantially the entire upper surface of the base material 21 with the heater 22 interposed therebetween. The ceramic plate 23 is a ceramic member made of, for example, aluminum oxide or aluminum nitride. The power supply line 41 that supplies high-frequency power from the high-frequency power supply 44 is connected, for example, to a lower surface of the ceramic plate 23.

The ceramic plate 23 has a flat upper surface. The upper surface of the ceramic plate 23 is the upper surface of the electrostatic chuck 20, and serves as a mounting surface on which the wafer 100 is to be mounted. A plurality of recessed portions 23r are provided on the upper surface of the ceramic plate 23. Each of the above-mentioned protruding portions 25 is fitted into each of the recessed portions 23r with a spring member 26 interposed therebetween.

The chuck electrode 24 as a power supply plate has a predetermined pattern, and is built in the ceramic plate 23 over substantially the entire surface of the ceramic plate 23.

Each of the spring members 26 as an elastic member is, for example, a compression coil spring or the like, and includes a base material made of ceramics such as silicon nitride, and a coating film made of an electrically conductive material such as tungsten. However, materials of the base material and coating film of the spring member 26 are not limited to those described above.

The base material 21 just needs to be a heat resistant material that can withstand such heating of 650° C. or higher by the above-mentioned heater 22. The coating film just needs to be made of a material having electrical conductivity and heat resistance to 650° C. or higher, and preferably, is made of a material having a melting point, for example, of 3000° C. or higher. As the coating film, for example, platinum or the like can be used as well as tungsten mentioned above.

Such a coating film as described above can be formed, for example, by performing sputtering processing, electroless plating processing, or the like for the base material molded into a shape of a compression spring or the like.

Each of the protruding portions 25 is configured by including, in an inside thereof, an electrically conductive member 25m covered with a cap 25c, and is supported by the spring member 26 so as to protrude from the upper surface of the ceramic plate 23. The spring member 26 is joined to a lower surface of the electrically conductive member 25m. The electrically conductive member 25m and the spring member 26 are electrically conductive to each other. Each of the protruding portions 25 has, for example, a columnar shape such as a cylindrical shape and a polygonal column shape. A diameter of each of the protruding portions 25 can be set, for example, to a few millimeters, and may be 2 mm for example.

The electrically conductive member 25m is made of metal such as tungsten for example. However, the electrically conductive member 25m just needs to be made of a material having electrical conductivity and heat resistance to 650° C. or higher, and preferably, is made of a material having a melting point, for example, of 3000° C. or higher. As the electrically conductive member 25m, for example, platinum or the like can be used as well as tungsten mentioned above.

Each of the caps 25c covers surfaces of the electrically conductive member 25m except the lower surface. In a similar way to the ceramic plate 23, the cap 25c can be made of ceramics made of, for example, aluminum oxide or aluminum nitride.

With such a configuration, the protrusion amount of the protruding portion 25 from the ceramic plate 23 changes depending on whether or not the wafer 100 is present on the electrostatic chuck 20. That is, when the wafer 100 is mounted on the electrostatic chuck 20, the above-mentioned spring member 26 contracts due to weight of the wafer 100, and the protrusion amount of the protruding portion 25 decreases.

The protrusion amount of the protruding portion 25 can be set to several ten micrometers in a state where the protruding portion 25 receives the weight of the wafer 100 and sinks to the deepest depth into the recessed portion 23r. The protrusion amount may be 30 μm for example. Further, preferably, elastic force of the spring member 26 is adjusted so that a maximum variation of the protrusion amount of the protruding portion 25 becomes, for example, several millimeters.

Moreover, the wafer 100 to be processed in the chamber 11 is sometimes warped. In a manufacturing process of a semiconductor device, a variety of films different in stress are formed on the wafer 100, and the wafer 100 is sometimes warped so as to protrude upward or downward due to stresses of those films. The example of FIG. 3 illustrates a state where the wafer 100 warped so as to protrude downward is mounted.

In this case, as going toward the center of the electrostatic chuck 20, the weight of the wafer 100, which is applied to the protruding portions 25, increases, the protruding portions 25 sink greatly into the recessed portions 23r of the ceramic plate 23. Meanwhile, on the outer edge portion of the electrostatic chuck 20, the weight of the wafer 100, which is applied to the protruding portions 25, decreases, a sinking amount of the protruding portions 25 is relatively small as compared with that on the central portion, and the protruding portions 25 protrude more.

As described above, the protrusion amount of each of the protruding portions 25 changes in accordance with the shape of the wafer 100, whereby a state is maintained in which the protruding portions 25 are in contact with substantially the entire back surface of the wafer 100. Hence, the wafer 100 is supported by substantially all of the plurality of protruding portions 25.

Further, with the above-described configuration, each of the protruding portions 25 transmits electrostatic force, which is generated by the chuck electrode 24, to the back surface of the wafer 100 via the internal electrically conductive member 25m and the spring member 26 joined to the electrically conductive member 25m, and can electrostatically attract the wafer 100 to the upper surface of the electrostatic chuck 20.

Moreover, with the above-described configuration, via the internal electrically conductive member 25m and the spring member 26 joined to the electrically conductive member 25m, each of the protruding portions 25 transmits heat, which comes from the heater 22, to the wafer 100 mounted on the upper surface of the electrostatic chuck 20, and can heat the wafer 100.

(Example of Plasma Processing)

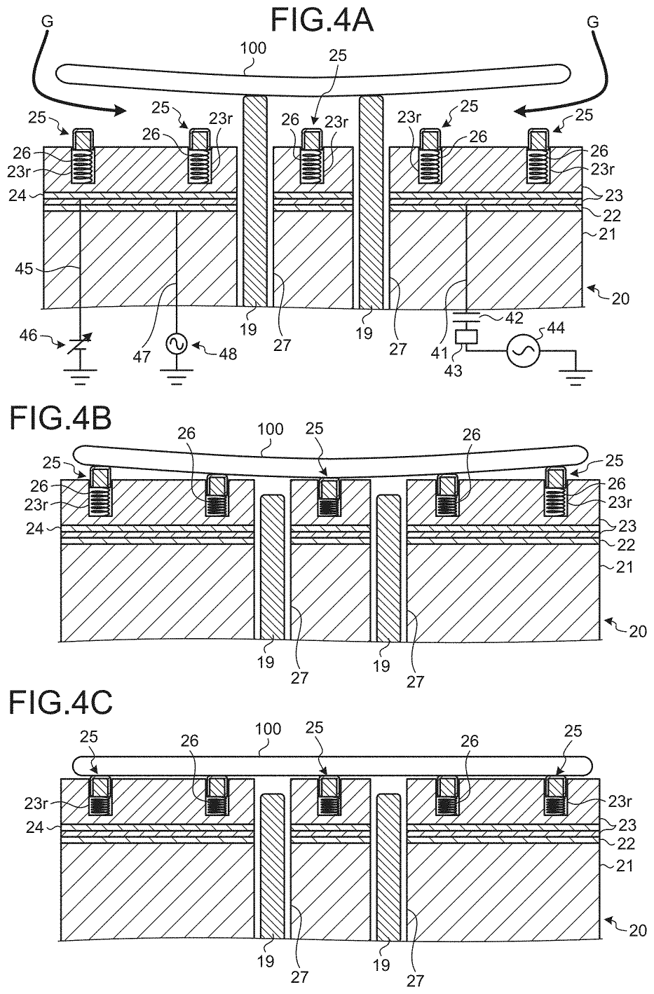

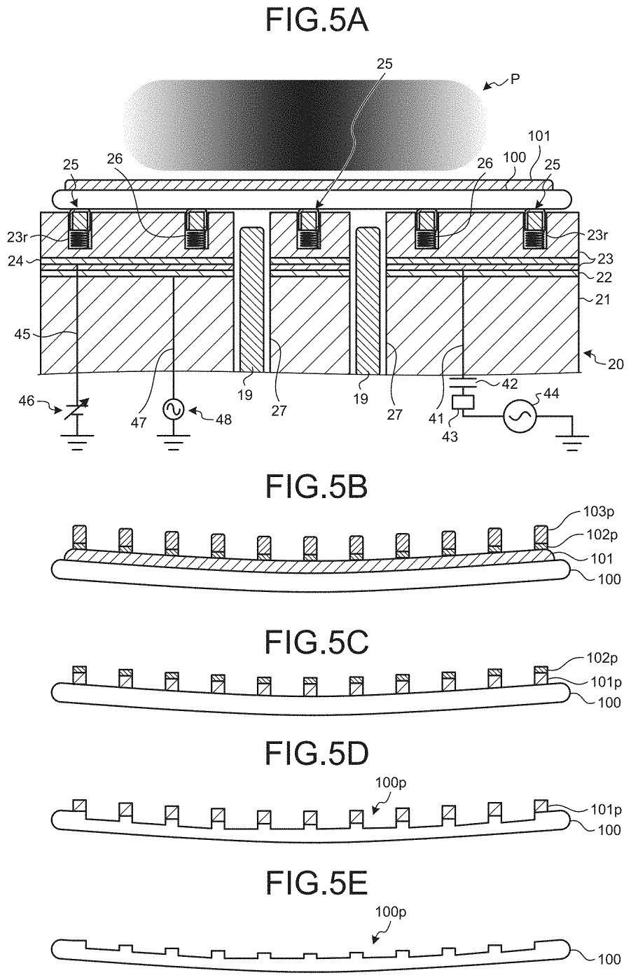

Next, referring to FIGS. 4A to 5E, a description will be given of an example the plasma processing for the wafer 100 in the plasma processing apparatus 1 of the first embodiment.

FIGS. 4A to 4C are cross-sectional views illustrating an example of a procedure of the plasma processing in the plasma processing apparatus 1 according to the first embodiment. FIGS. 5A to 5E are cross-sectional views illustrating an example of a procedure of the plasma processing in the plasma processing apparatus 1 according to the first embodiment and processing subsequent to the plasma processing. The plasma processing and the processing subsequent thereto in FIGS. 4A to 5E are implemented as a part of a process of manufacturing a semiconductor device.

The processing illustrated in FIGS. 4A and 4B is preheating of preliminarily heating the wafer 100.

As illustrated in FIG. 4A, in accordance with the control of the control unit 50, the wafer 100 is carried into the chamber 11, the lift pins 19 are lifted, and the wafer 100 is supported by the lift pins 19. The example of FIG. 4A illustrates a state where the wafer 100 warped so as to protrude downward is supported by the lift pins 19. The wafer 100 is located at a position apart from the upper surface of the electrostatic chuck 20. Accordingly, at this time, the plurality of protruding portions 25 are in an initial state, and protrude by a substantially maximum protrusion amount from the upper surface of the ceramic plate 23.

Further, in accordance with the control of the control unit 50, alternating-current power is supplied from the power supply 48 to the heater 22, and the heater 22 is heated, for example, to 650° C. or higher. Moreover, from the gas outlet ports 18g of the shower head 18, processing gas, inert gas, or the like is supplied into the chamber 11. In this state, the wafer 100 is maintained for a predetermined time at a position above the electrostatic chuck 20.

Thus, the wafer 100 is heated by heat radiation from the heater 22. Further, the gas supplied from the gas outlet ports 18g runs around to the back surface of the wafer 100, and the heat transfer between the heater 22 and the wafer 100 is promoted also by the gas.

As illustrated in FIG. 4B, after the elapse of a predetermined time, the lift pins 19 are lowered and housed in the lift pin housing holes 27 in accordance with the control of the control unit 50. Thus, the wafer 100 is mounted on the ceramic plate 23 of the electrostatic chuck 20. More strictly, the wafer 100 is supported by the plurality of protruding portions 25 which protrude from the upper surface of the ceramic plate 23.

For example, the wafer 100 is warped so as to protrude downward. Accordingly, larger weight is applied to the protruding portions 25 arranged near the center of the ceramic plate 23, and the spring member 26 also contracts to a great extent. Accordingly, the protrusion amount of each of the protruding portions 25 from the ceramic plate 23 is reduced.

Further, only small weight is applied to the protruding portions 25 arranged near an outer edge portion of the ceramic plate 23, and the spring member 26 also contracts to a smaller extent. Accordingly, the protrusion amount of each of the protruding portions 25 from the ceramic plate 23 remains large.

As described above, in accordance with arrangement positions of the protruding portions 25 on the ceramic plate 23, the protrusion amount of each of the protruding portions 25 changes, and the plurality of protruding portions 25 follow the shape of the back surface of the wafer 100. Accordingly, the contact between the wafer 100 and the protruding portions 25 is maintained on substantially the entire back surface of the wafer 100. The wafer 100 is maintained in this state for a predetermined time.

Thus, the wafer 100 is heated by the heat radiation from the heater 22. Moreover, the heat from the heater 22 is transmitted to the wafer 100 also via the spring members 26 and the electrically conductive members 25m of the protruding portions 25, and the heating of the wafer 100 is promoted. At this time, substantially the entire back surface of the wafer 100 is in contact with the plurality of protruding portions 25. Accordingly, the entire wafer 100 is heated substantially uniformly.

As described above, the preheating illustrated in FIGS. 4A and 4B is performed, whereby the wafer 100 can be rapidly heated up to a processing temperature at the following plasma processing. Further, when the wafer 100 is warped, the wafer 100 is softened to easily reduce the warp by the preheating in FIGS. 4A and 4B. Thus, the shock at the time of attracting the wafer 100 to the electrostatic chuck 20 can be absorbed.

As illustrated in FIG. 4C, after the elapse of a predetermined time, in accordance with the control of the control unit 50, direct-current power is supplied from the power supply 46 to the chuck electrode 24, and the wafer 100 is electrostatically attracted onto the ceramic plate 23. More strictly, the wafer 100 is attracted to the plurality of protruding portions 25 which protrude from the upper surface of the ceramic plate 23, and some gap is maintained between the wafer 100 and the upper surface of the ceramic plate 23.

Thus, even if the wafer 100 is warped, the wafer 100 becomes substantially flat, and is attracted onto the ceramic plate 23. Further, by the fact that the wafer 100 is attracted by electrostatic force, the contraction of the spring members 26 is substantially maximized, and the protrusion amount of each of the protruding portions 25 from the ceramic plate 23 is substantially minimized.

As illustrated in FIG. 5A, in accordance with the control of the control unit 50, the processing gas is supplied into the chamber 11 from the gas outlet ports 18g of the shower head 18. Moreover, high-frequency power is supplied from the high-frequency power supply 44 to the ceramic plate 23. Thus, plasma is generated above the wafer 100 in the chamber 11 by the planar/parallel electrodes made of the shower head 18 and the electrostatic chuck 20.

Further, in accordance with the control of the control unit 50, inert gas or the like is flown into the gap between the back surface of the wafer 100 and the ceramic plate 23, and the heat transfer between the heater 22 and the wafer 100 is promoted.

Thus, the wafer 100 in the chamber 11 is subjected to the plasma processing. The example of FIG. 5A illustrates a state where a carbon film 101 is formed on the upper surface of the wafer 100 by the plasma processing. The carbon film 101 is an organic film formed by CVD, and is used as a mask material or the like in the manufacturing process of the semiconductor device.

The wafer 100 on which the carbon film 101 is formed is carried out of the plasma processing apparatus 1, and in another apparatus, for example, a spin on glass (SOG) film is formed on the carbon film 101, and a resist film is formed on the SOG film.

Processing illustrated in FIGS. 5B to 5E is an example of the processing in that another apparatus after the processing in the plasma processing apparatus 1 is ended.

As illustrated in FIG. 5B, a resist pattern 103p is formed by exposure of the resist film, the SOG film is subjected to etching processing by using the resist pattern 103p as a mask, and an SOG pattern 102p is formed.

As illustrated in FIG. 5C, the carbon film 101 is subjected to the etching processing by using the SOG pattern 102p as a mask, and a carbon pattern 101p is formed. By this processing, for example, the resist pattern 103p disappears.

As illustrated in FIG. 5D, the wafer 100 is subjected to the etching processing by using the carbon pattern 101p as a mask, and a pattern 100p is formed on the surface of the wafer 100. As illustrated in FIG. 5E, the carbon pattern 101p is subjected, for example, to ashing removal.

Such processing as described above is repeated, whereby the semiconductor device is manufactured.

### Comparative Example

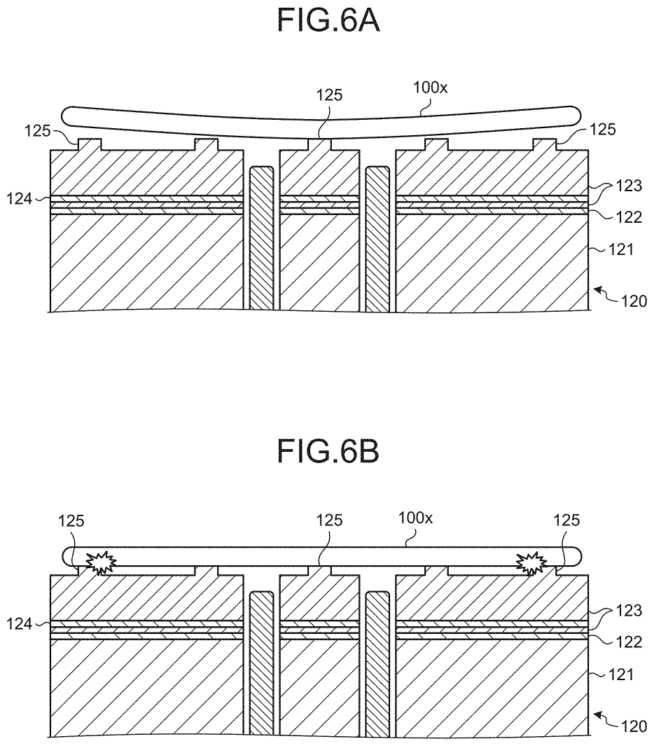

Next, referring to FIGS. 6A and 6B, a description will be given of an example of preheating a wafer 100x in a plasma processing apparatus of a comparative example. FIGS. 6A and 6B are cross-sectional views illustrating an example of a procedure of preheating in the plasma processing apparatus according to the comparative example.

As illustrated in FIG. 6A, the plasma processing apparatus of the comparative example includes an electrostatic chuck 120 having a base material 121, a heater 122, a ceramic plate 123, and a chuck electrode 124. The ceramic plate 123 of the electrostatic chuck 120 includes a plurality of protruding portions 125 on an upper surface thereof. The plurality of protruding portions 125 are those formed, for example, by embossing the upper surface of the ceramic plate 123, are made of a material similar to that of the ceramic plate 123, and protrude in a fixed manner from the upper surface of the ceramic plate 123.

For example, when the wafer 100x illustrated in FIG. 6A is warped so as to protrude downward at the time of preheating the wafer 100x, an outer edge portion of the wafer 100x is maintained in a non-contact state with the protruding portions 125. Thus, it takes long to preheat the wafer 100x, and further, the entirety of the wafer 100x is not heated uniformly, and for example, the temperature of the outer edge portion of the wafer 100x remains low.

As illustrated in FIG. 6B, when direct-current power is supplied to the chuck electrode 124 to attract the wafer 100x to the ceramic plate 123 after the preheating, the outer edge portion of the wafer 100x is hit against the protruding portions 125 which are in non-contact with the wafer 100x, and a strong shock is sometimes applied to the back surface of the outer edge portion of the wafer 100x.

Thus, the back surface of the wafer 100x is sometimes scratched, and particles are sometimes generated in the chamber. At this time, the position of the wafer 100x shifts to sometimes cause an error in carrying the wafer 100x. Further, when the back surface of the wafer 100x is scratched, such a scratch becomes a source of the particles in the subsequent processing, and in addition, may cause a break, a chip, and the like of the wafer 100x.

In order to suppress a scratch of the wafer 100x due to friction, for example, it is also conceived to form the protruding portions of flexible resin such as poly tetra fluoro ethylene (PTFE).

However, with regard to such protruding portions as described above, a protrusion amount of each thereof from the ceramic plate 123 is fixed, and the protruding portions cannot obtain, for example, sufficient followability for the wafer 100x that is warped. Further, for example, a melting point of PTFE is approximately 350° C., and it is apprehended that the protruding portions may be deformed or denatured at a high temperature of 650° C. or higher.

The electrostatic chuck 20 of the embodiment includes the plurality of protruding portions 25 and the plurality of spring members 26. Thus, at the time of attracting the wafer 100 to the electrostatic chuck 20, the shock can be absorbed by the spring members 26, and a damage of the warped wafer 100 can be suppressed. Further, the plurality of protruding portions 25 can be caused to follow the shape of the back surface of the wafer 100, and the entirety of the wafer 100 can be heated uniformly at the time of preheating the wafer 100.

In accordance with the electrostatic chuck 20 of the embodiment, the plurality of protruding portions 25 include the electrically conductive members 25m in the insides, and the spring members 26 have electrically conductive coating films which electrically connect the chuck electrode 24 and the electrically conductive members 25m to each other. Thus, the wafer 100 electrically conducts to the chuck electrode 24, and can be attracted to the electrostatic chuck 20 more surely. Further, the transfer of the heat to the wafer 100 is improved, and a preheating time can be shortened.

In accordance with the electrostatic chuck 20 of the embodiment, the plurality of protruding portions 25 are arranged on the entire mounting surface of the ceramic plate 23, for example, in a radially dispersed manner. Thus, the weight of the wafer 100 can be dispersed to the plurality of protruding portions 25, and the scratch of the back surface of the wafer 100 can be suppressed by further absorbing the shock to the wafer 100.

In accordance with the electrostatic chuck 20 of the embodiment, the plurality of protruding portions 25 and the plurality of spring members 26 have heat resistance. Thus, these protruding portions 25 and spring members 26 can be suppressed from being deformed or degraded, for example, by heat at a temperature of 650° C. or higher.

In the above-mentioned first embodiment, the description has been given of the example of the case where the wafer 100 is warped so as to protrude downward. However, the electrostatic chuck 20 of the first embodiment has a similar effect also for the wafer 100 warped so as to protrude upward.

Further, in the above-mentioned first embodiment, in the plasma processing apparatus 1, the high-frequency voltage is applied to the lower electrode; however, the high-frequency power may be applied to the upper electrode, or may be applied to the upper and lower electrodes. Besides, the plasma processing apparatus may be an apparatus that uses other plasma sources such as inductively coupled plasma (ICP).

Further, in the above-mentioned first embodiment, it is defined that the plasma processing apparatus 1 is a CVD apparatus that forms a predetermined film on the wafer 100; however, no limitations are imposed thereon. For example, the configuration of the above-mentioned electrostatic chuck 20 is also applicable to a substrate processing apparatus such as an etching apparatus and an ashing apparatus, which processes the wafer 100 at a low pressure.

### First and Second Modified Examples

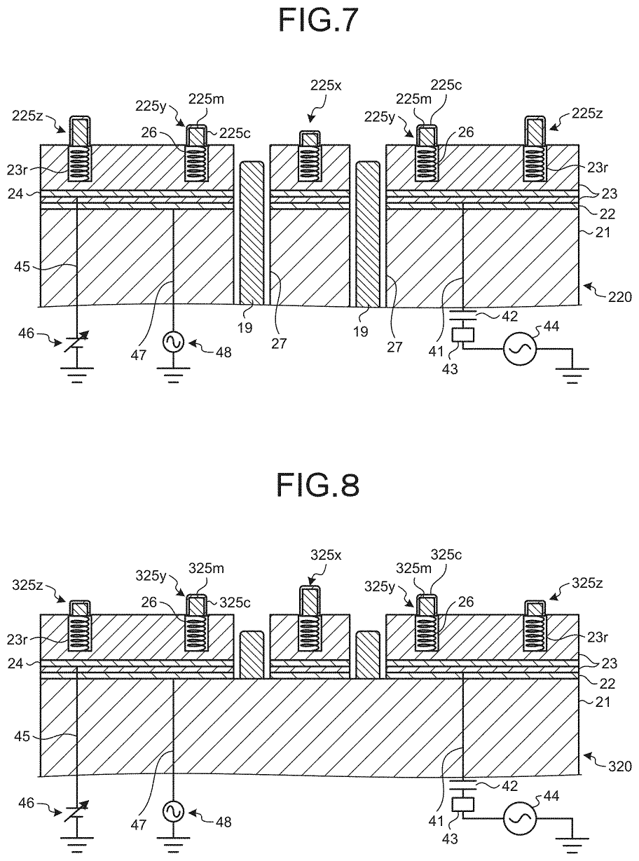

Next, referring to FIGS. 7 and 8, a description will be given of electrostatic chucks 220 and 320 of first and second modified examples of the first embodiment. The first and second modified examples are different from the above-mentioned first embodiment in that, in each of the electrostatic chucks 220 and 320 thereof, protrusion amounts of a plurality of protruding portions from the ceramic plate 23 are different from one another.

FIG. 7 is a view illustrating a cross-sectional structure of the electrostatic chuck 220 provided in a plasma processing apparatus according to the first modified example of the first embodiment. As illustrated in FIG. 7, the electrostatic chuck 220 includes a plurality of protruding portions 225x, 225y, and 225z.

Each of the plurality of protruding portions 225x, 225y, and 225z is configured by including, in an inside thereof, an electrically conductive member 225m covered with a cap 225c, and is supported by the spring member 26 so as to protrude from the upper surface of the ceramic plate 23. The electrically conductive member 225m and the cap 225c may be configured with materials similar to those of the electrically conductive member 25m and the cap 25c in the above-mentioned first embodiment.

The protruding portion 225x as a first protruding portion is arranged in the recessed portion 23r provided on the central region of the ceramic plate 23. A longitudinal dimension of the protruding portion 225x is the shortest among those of the plurality of protruding portions 225x, 225y, and 225z, and in the initial state, the protrusion amount of the protruding portion 225x from the ceramic plate 23 is the smallest.

The protruding portions 225y are arranged in the recessed portions 23r provided between the central region of the ceramic plate 23 and an outer edge region thereof. A longitudinal dimension of the protruding portions 225y is longer than that of the protruding portion 225x and shorter than that of the protruding portions 225z, and in the initial state, the protrusion amount of the protruding portions 225y from the ceramic plate 23 is larger than that of the protruding portion 225x and smaller than that of the protruding portions 225z.

The protruding portions 225z as second protruding portions are arranged in the recessed portions 23r provided on the outer edge region of the ceramic plate 23. A longitudinal dimension of the protruding portions 225z is the longest among those of the plurality of protruding portions 225x, 225y, and 225z, and in the initial state, the protrusion amount of the protruding portions 225z from the ceramic plate 23 is the largest.

Such an electrostatic chuck 220 as described above can be applied, for example, to a plasma processing apparatus that processes a large number of wafers warped so as to protrude downward. In the initial state, the protrusion amounts of the plurality of protruding portions 225x, 225y, and 225z are different from one another as described above. Accordingly, the followability of the protruding portions to the wafers which protrude downward is further improved.

FIG. 8 is a view illustrating a cross-sectional structure of the electrostatic chuck 320 provided in a plasma processing apparatus according to the second modified example of the first embodiment. As illustrated in FIG. 8, the electrostatic chuck 320 includes a plurality of protruding portions 325x, 325y, and 325z.

Each of the plurality of protruding portions 325x, 325y, and 325z is configured by including, in an inside thereof, an electrically conductive member 325m covered with a cap 325c, and is supported by the spring member 26 so as to protrude from the upper surface of the ceramic plate 23. The electrically conductive member 325m and the cap 325c may be configured with materials similar to those of the electrically conductive member 25m and the cap 25c in the above-mentioned first embodiment.

The protruding portion 325x as a first protruding portion is arranged in the recessed portion 23r provided on the central region of the ceramic plate 23. A longitudinal dimension of the protruding portion 325x is the longest among those of the plurality of protruding portions 325x, 325y, and 325z, and in the initial state, the protrusion amount of the protruding portion 325x from the ceramic plate 23 is the largest.

The protruding portions 325y are arranged in the recessed portions 23r provided between the central region of the ceramic plate 23 and the outer edge region thereof. A longitudinal dimension of the protruding portions 325y is shorter than that of the protruding portion 325x and longer than that of the protruding portions 325z, and in the initial state, the protrusion amount of the protruding portions 325y from the ceramic plate 23 is smaller than that of the protruding portion 325x and larger than that of the protruding portions 325z.

The protruding portions 325z as third protruding portions are arranged in the recessed portions 23r provided on the outer edge region of the ceramic plate 23. A longitudinal dimension of the protruding portions 325z is the shortest among those of the plurality of protruding portions 325x, 325y, and 325z, and in the initial state, the protrusion amount of the protruding portions 325z from the ceramic plate 23 is the smallest.

Such an electrostatic chuck 320 as described above can be applied, for example, to a plasma processing apparatus that processes a large number of wafers warped so as to protrude upward. In the initial state, the protrusion amounts of the plurality of protruding portions 325x, 325y, and 325z are different from one another as described above. Accordingly, the followability of the protruding portions to the wafers which protrude upward is further improved.

Note that the protrusion amounts of the plurality of protruding portions may be changed in three stages as described above, or alternatively, may be changed in two stages or four stages or more. Further, in place of or in addition to the change of the longitudinal dimensions of the plurality of protruding portions, longitudinal dimensions of the spring members 26 are changed, whereby the protrusion amounts of the protruding portions may be changed.

### Third and Fourth Modified Examples

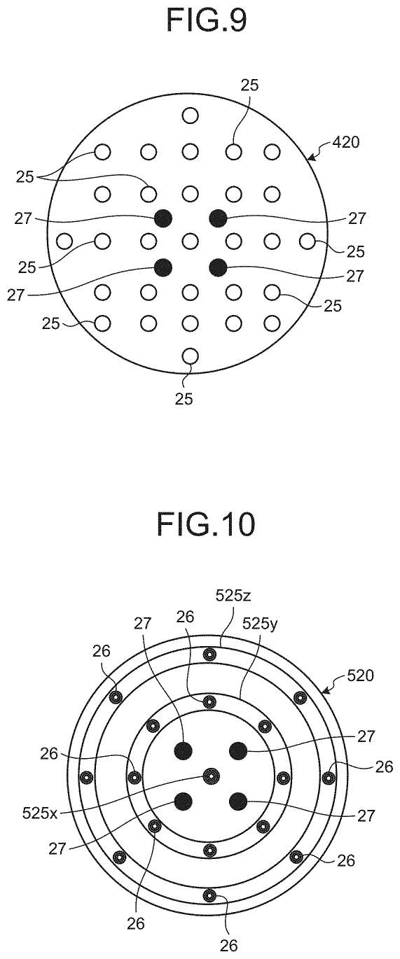

Next, referring to FIGS. 9 and 10, a description will be given of electrostatic chucks 420 and 520 of third and fourth modified examples of the first embodiment. The third and fourth modified examples are different from the above-mentioned first embodiment in terms of arrangement and shape of a plurality of protruding portions in each of the electrostatic chucks 420 and 520 thereof.

FIG. 9 is a top view of the electrostatic chuck 420 provided in a plasma processing apparatus according to the third modified example of the first embodiment. As illustrated in FIG. 9, the electrostatic chuck 420 includes a plurality of protruding portions 25 similar to those of the above-mentioned first embodiment. However, the plurality of protruding portions 25 are arranged on the upper surface of the electrostatic chuck 420 in a pattern different from that in the above-mentioned first embodiment.

More specifically, the plurality of protruding portions 25 are arranged on the entire upper surface of the electrostatic chuck 420 in a dispersed manner in a grid fashion. That is, the plurality of protruding portions 25 are arranged on the respective intersections of a lattice pattern.

FIG. 10 is a top view of the electrostatic chuck 520 provided in a plasma processing apparatus according to the fourth modified example of the first embodiment. As illustrated in FIG. 10, the electrostatic chuck 520 includes a plurality of protruding portions 525x, 525y, and 525z.

For example, the protruding portion 525x has a columnar shape such as a cylindrical shape and a polygonal columnar shape, and is arranged on the central region of the upper surface of the electrostatic chuck 520. Each of the protruding portions 525y and 525z has an annular shape, and is arranged concentrically with each other on the upper surface of the electrostatic chuck 520. The protruding portion 525y is arranged between the central region of the upper surface of the electrostatic chuck 520 and an outer edge region thereof so as to surround the protruding portion 525x. The protruding portion 525z is arranged on the outer edge region of the electrostatic chuck 520 so as to surround the protruding portion 525y.

The number of each of the protruding portions 525x, 525y, and 525z is arbitrary. Further, each of the protruding portions 525y and 525z may have such a continuous annular shape as mentioned above, or alternatively, may have an intermittent annular shape, that is, a shape formed by combining a plurality of circular arcs with one another into a circular shape.

Each of the annular protruding portions 525y and 525z includes, for example, an annular electrically conductive member (not illustrated) as a core material. A cap (not illustrated) covers a side surface of the electrically conductive member, which faces the central region, a side surface of the electrically conductive member, which faces the outer edge region, and an upper surface of the electrically conductive member. Thus, the spring members 26 can be joined to the lower surface of the electrically conductive member.

Further, in the above-described configuration, the spring members 26 may be arranged at a plurality of positions below each of the protruding portions 525y and 525z. The example of FIG. 10 illustrates a state where the plurality of spring members 26 are radially arranged along a circumferential direction of each of the protruding portions 525y and 525z, for example, from the central portion of the upper surface of the electrostatic chuck 520 toward the outer edge portion thereof.

The arrangement of the plurality of spring members 26 is not limited to this. Further, when each of the protruding portions 525y and 525z is divided into some circular arcs, at least one spring member 26 may be disposed below each divided piece of each of the protruding portions 525y and 525z.

In accordance with the electrostatic chucks 420 and 520 of the third and fourth modified examples, similar effects to those of the electrostatic chuck 20 of the above-mentioned first embodiment are exerted.

### Second Embodiment

A second embodiment will be described below in detail with reference to the drawings. The second embodiment is different from the above-mentioned first embodiment in that a substrate supporting apparatus sucks and attracts a wafer.

(Configuration Example of Exposure Processing Apparatus)

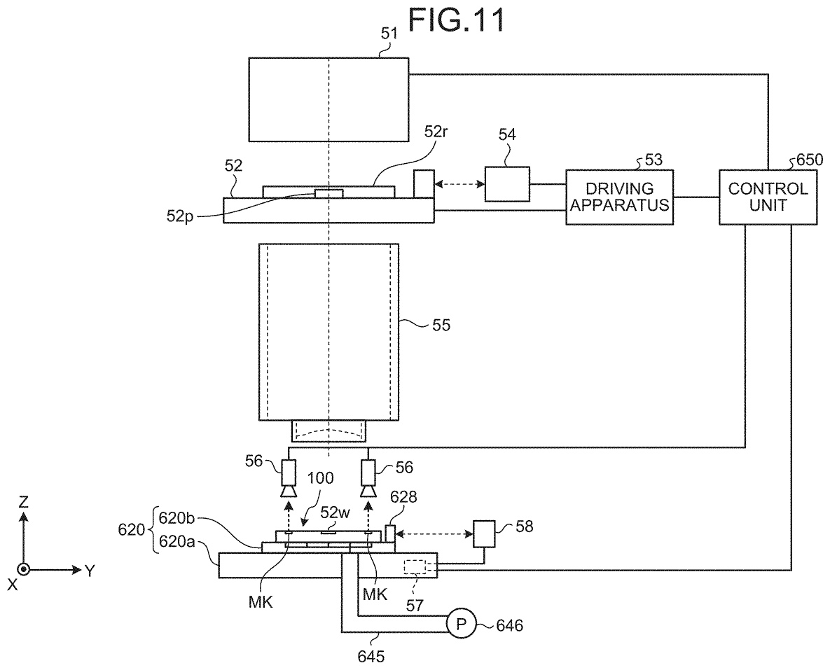

FIG. 11 is a diagram schematically illustrating an example of a configuration of an exposure processing apparatus 2 according to the second embodiment.

As illustrated in FIG. 11, the exposure processing apparatus 2 as a substrate processing apparatus includes a lighting unit 51, a reticle stage 52, driving apparatuses 53 and 57, interferometers 54 and 58, a projection unit 55, mark detectors 56, a mounting table 620, and a pump 646. These respective units are controlled by a control unit 650.

The mounting table 620 as a substrate supporting apparatus includes a main body 620a and a wafer chuck 620b, and movably supports the wafer 100. The driving apparatus 57 includes a motor (not illustrated), and moves the mounting table 620 in an X-axis direction and a Y-axis direction, which are horizontal to the wafer 100, and in a Z-axis direction perpendicular to the wafer 100.

The position of the mounting table 620 is measured by the interferometer 58 from a reference mark 628 provided on the mounting table 620, and a result of the measurement is input to the driving apparatus 57. The driving apparatus 57 controls the position of the mounting table 620 by using the result of the measurement by the interferometer 58. The wafer 100 moves as the mounting table 620 moves.

The mark detectors 56 detect marks Mk provided on the wafer 100, and sends position information to the control unit 650. The control unit 650 aligns the wafer 100 in accordance with the position information. The mark detectors 56 are imaging elements such as CCD and CMOS sensors for example.

The plurality of imaging elements as the mark detectors 56 individually detect the corresponding marks Mk, the position of the mounting table 620 is adjusted by the control unit 650 in accordance with positions of the detected marks Mk, and the position of the wafer 100 is aligned with respect to the lighting unit 51.

The reticle stage 52 supports a reticle 52r in which a circuit pattern is drawn on a region 52p. The driving apparatus 53 includes a motor (not illustrated), and moves the reticle stage 52 with respect to the wafer 100 at least on the horizontal plane.

The position of the reticle stage 52 is measured by the interferometer 54, and a result of the measurement is input to the driving apparatus 53. The driving apparatus 53 controls the position of the reticle stage 52 on the basis of the result of the measurement by the interferometer 54. The reticle 52r moves as the reticle stage 52 moves.

The lighting unit 51 applies exposure light to a range of a region 52p on the reticle 52r. The projection unit 55 projects the exposure light, which transmits through the reticle 52r, onto a range of a region 52w of a resist film (not illustrated) on the wafer 100. Thus, the circuit pattern drawn on the reticle 52r is transferred to the resist film.

The pump 646 is connected to the mounting table 620 via an vacuum port 645. The vacuum port 645 is branched into a plurality of suction paths which reach the back surface of the wafer 100 in the inside of the wafer chuck 620b of the mounting table 620. The back surface of the wafer 100 is sucked by the pump 646, whereby the wafer 100 can be sucked and attracted to the upper surface of the wafer chuck 620b.

The wafer 100 is subjected to exposure processing in the exposure processing apparatus 2 having the above configuration, whereby, for example, the resist pattern 103p illustrated in FIG. 5B of the above-mentioned first embodiment is formed on the wafer 100.

(Configuration Example of Wafer Chuck)

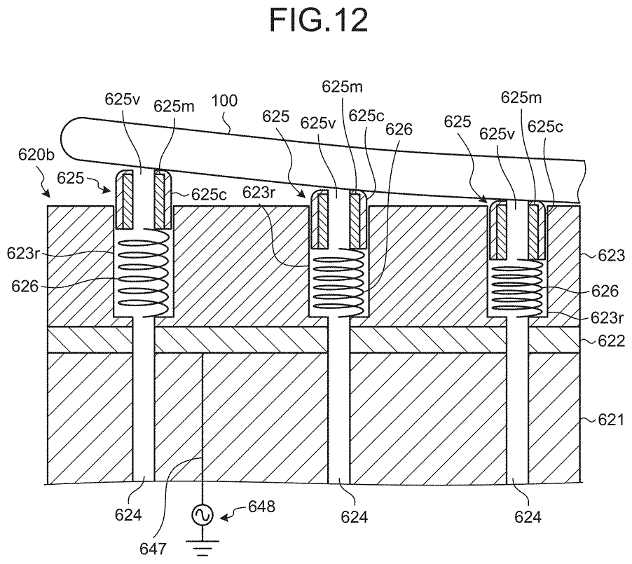

Next, a detailed configuration of the wafer chuck 620b will be described with reference to FIG. 12.

FIG. 12 is a view illustrating a cross-sectional structure of the wafer chuck 620b according to the second embodiment. In FIG. 12, the vicinity of the outer edge portion of the wafer chuck 620b is enlargedly illustrated. As illustrated in FIG. 12, the wafer chuck 620b includes, as a cross-sectional structure, a base material 621, a heater 622, and a ceramic plate 623.

The base material 621 is a main body of the wafer chuck 620b, and is made of aluminum for example. The base material 621 has a flat upper surface. The base material 621 is provided with a plurality of suction paths 624 which penetrate the base material 621 in a plate thickness direction. The plurality of suction paths 624 are connected to the vacuum port 645 that communicates with the pump 646, and are arranged in a dispersed manner in the entire upper surface of the base material 621.

The heater 622 as an electric heating plate has a predetermined pattern, and is disposed on substantially the entire upper surface of the base material 621. The heater 622 is disposed so as to detour the suction paths 624 of the base material 621 by having a predetermined pattern.

The heater 622 constitutes a part of a heating mechanism that heats the wafer 100. That is, the heating mechanism includes the heater 622, a power supply line 647, and a power supply 648 as a third power supply. To the heater 622, the power supply 648 that supplies power to the heater 622 is connected via the power supply line 647.

By such a mechanism as described above, alternating-current power is supplied from the power supply 648 to the heater 622, and the heater 622 is heated. Thus, the wafer 100 mounted on the wafer chuck 620b can be heated.

The ceramic plate 623 as a mounting plate is formed into a shape of a flat plate that covers substantially the entire upper surface of the base material 621 with the heater 622 interposed therebetween. The ceramic plate 623 is a ceramic member made of, for example, aluminum oxide or aluminum nitride.

The ceramic plate 623 has a flat upper surface. The upper surface of the ceramic plate 623 is the upper surface of the wafer chuck 620b, and serves as a mounting surface on which the wafer 100 is to be mounted. A plurality of recessed portions 623r are provided on the upper surface of the ceramic plate 623.

Each of the recessed portions 623r is connected to the suction path 624 provided in the base material 621. Further, each of protruding portions 625 is fitted into each of the recessed portions 623r with a spring member 626 interposed therebetween.

Each of the spring members 626 as an elastic member is, for example, a compression coil spring or the like, and includes a base material made of ceramics such as silicon nitride, and a coating film made of a thermally conductive material such as tungsten. However, materials of the base material and coating film of the spring member 626 are not limited to those described above.

The base material just needs to be a heat resistant material that can withstand heating by the above-mentioned heater 622. The coating film just needs to be a thermally conductive material capable of transmitting heat of the above-mentioned heater 622 to the wafer 100. As the coating film, for example, platinum or the like can be used as well as tungsten mentioned above. Note that the coating film can be formed as in the case of the spring members 26 of the above-mentioned first embodiment.

The plurality of protruding portions 625 protrude from the upper surface of the wafer chuck 620b, and are arranged in a dispersed manner on the entire upper surface of the wafer chuck 620b. More specifically, each of the plurality of protruding portions 625 has a columnar shape such as a cylindrical shape and a polygonal columnar shape, and for example, can adopt a variety of arrangements, for example, illustrated in the first embodiment, the third modified example, and the like, which are mentioned above. At this time, a diameter of each of the protruding portions 625 can be set, for example, to a few millimeters, and may be 2 mm for example. The plurality of protruding portions 625 may have concentric annular shapes illustrated in the fourth modified example of the above-mentioned first embodiment.

Each of the protruding portions 625 is configured by including, in an inside thereof, a thermally conductive member 625m covered with a cap 625c, and is supported by the spring member 626 so as to protrude from the upper surface of the ceramic plate 623.

The thermally conductive member 625m is made of metal such as tungsten for example. The thermally conductive member 625m just needs to be made of a material having thermal conductivity and heat resistance, and for example, can be made of thermally conductive ceramics as well as metal such as platinum. The spring member 626 is joined to a lower surface of the thermally conductive member 625m.

Each of the caps 625c covers surfaces of the thermally conductive member 625m except the lower surface. In a similar way to the ceramic plate 623, the cap 625c can be made of ceramics made of, for example, aluminum oxide or aluminum nitride.

Further, each of the protruding portions 625 includes a suction port 625v that penetrates the thermally conductive member 625m and the cap 625c that covers the upper surface of the thermally conductive member 625m. Thus, in the wafer chuck 620b, paths are formed, each of which departs from the suction path 624 of the base material 621, passes through the recessed portion 623r of the ceramic plate 623, a void contained in the spring member 626, and the suction port 625v of the protruding portion 625, and reaches the back surface of the wafer 100. The formation of the paths makes it possible to suck and attract the wafer 100 by the pump 646.

With such a configuration, when the wafer 100 is mounted on the wafer chuck 620b, the above-mentioned spring member 626 contracts due to weight of the wafer 100, and the protrusion amount of the protruding portion 625 decreases. The protrusion amount of the protruding portion 625 can be set to several ten micrometers in a state where the protruding portion 625 sinks to the deepest depth into the recessed portion 623r. The protrusion amount may be 30 μm for example. Further, preferably, elastic force of the spring member 626 is adjusted so that a maximum variation of the protrusion amount of the protruding portion 625 becomes, for example, several millimeters.

Moreover, for example, even if the wafer 100 is warped, the plurality of protruding portions 625 can be caused to follow the shape of the back surface of the wafer 100, and can support the wafer 100. The example of FIG. 12 illustrates a state where the wafer 100 warped so as to protrude downward is mounted. In such a case, in a similar way to the first and second modified examples of the above-mentioned first embodiment, a longitudinal dimension of at least either each of the protruding portions 625 and each of the spring members 626 is adjusted, whereby the protrusion amount of the protruding portion 625 may be differentiated between the central region and outer edge region of the ceramic plate 623.

Further, with the above-described configuration, the protruding portions 625 transmit suction force, which is generated by the vacuum of the pump 646, to the back surface of the wafer 100 via the suction ports 625v provided in the protruding portions 625, and can suck and attract the wafer 100 to the upper surface of the wafer chuck 620b.

Moreover, with the above-described configuration, via the internal thermally conductive member 625m and the spring member 626 joined to the thermally conductive member 625m, each of the protruding portions 625 transmits heat, which comes from the heater 622, to the wafer 100 mounted on the upper surface of the wafer chuck 620b, and can heat the wafer 100.

In accordance with the mounting table 620 of the second embodiment, similar effects to those of the electrostatic chuck 20 of the above-mentioned first embodiment are exerted.

Note that, as well as to the exposure processing apparatus 2, the mounting table 620 of the above-mentioned second embodiment is also applicable, for example, to an imprint processing apparatus, or to a substrate processing apparatus such as a cleaning processing apparatus that processes the wafer 100 at normal pressure. The imprint processing apparatus is an apparatus that thrusts a template, which has a circuit pattern, against the resist film and the like on the wafer 100, and forms the resist pattern.

Further, some exposure processing apparatuses sometimes adopt a system of performing exposure processing for the wafer 100 under low pressure. To such exposure processing apparatuses as described above, for example, there can be applied the electrostatic chuck 20 of the electrostatic attraction system in the above-mentioned first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate supporting apparatus that supports a substrate in a processing container of a substrate processing apparatus, the substrate supporting apparatus comprising:
a mounting plate that is configured by including ceramics and has a mounting surface on which the substrate is to be mounted;
a power supply plate that is built in the mounting plate and electrostatically attracts the substrate to the mounting plate;
a plurality of protruding portions which internally includes an electrically conductive member respectively, is arranged on at least a central region and outer edge region of the mounting plate, and protrudes from the mounting surface; and
a plurality of elastic members which is embedded in the mounting plate to correspond to the plurality of protruding portions, supports the plurality of protruding portions while protruding the protruding portions from the mounting surface, and electrically connects the power supply plate and the electrically conductive members included in the plurality of protruding portions to each other.

2. The substrate supporting apparatus according to claim 1, further comprising,
below the mounting plate, an electric heating plate that heats the substrate.

3. The substrate supporting apparatus according to claim 1, wherein
the plurality of protruding portions is arranged on the entire mounting surface of the mounting plate.

4. The substrate supporting apparatus according to claim 3, wherein
the plurality of protruding portions
has columnar shapes, and is arranged on the mounting surface radially or in grid shapes, or
has annular shapes, and is arranged on the mounting surface concentrically.

5. The substrate supporting apparatus according to claim 1, wherein
the plurality of protruding portions includes:
a first protruding portion arranged on the central region; and
a second protruding portion which is arranged on the outer edge region and has a protrusion amount from the mounting surface, the protrusion amount being different from a protrusion amount of the first protruding portion.

6. The substrate supporting apparatus according to claim 5, wherein
the protrusion amount of the first protruding portion is larger than the protrusion amount of the second protruding portion.

7. The substrate supporting apparatus according to claim 5, wherein
the protrusion amount of the first protruding portion is smaller than the protrusion amount of the second protruding portion.

8. A substrate supporting apparatus that supports a substrate in a processing container of a substrate processing apparatus, the substrate supporting apparatus comprising:
a mounting plate that is configured by including ceramics and has a mounting surface on which the substrate is to be mounted;
a plurality of protruding portions which internally includes an electrically conductive or thermally conductive member respectively, is arranged on at least a central region and outer edge region of the mounting plate, and protrudes from the mounting surface; and
a plurality of elastic members which is embedded in the mounting plate to correspond to the plurality of protruding portions, and supports the plurality of protruding portions while protruding the protruding portions from the mounting surface.

9. The substrate supporting apparatus according to claim 8, further comprising
a power supply plate that electrostatically attracts the substrate to the mounting plate, wherein
the member is electrically a conductive member, and
the plurality of elastic members electrically connects the power supply plate and the electrically conductive members included in the plurality of protruding portions to each other.

10. The substrate supporting apparatus according to claim 8, wherein
the member is a thermally conductive member, and
the plurality of protruding portions has a suction port respectively for use in sucking and attracting the substrate to the mounting plate.

11. A substrate processing apparatus comprising:
a processing container for processing a substrate; and
a substrate supporting apparatus that supports the substrate in the processing container, wherein
the substrate supporting apparatus includes:
a mounting plate that is configured by including ceramics and has a mounting surface on which the substrate is to be mounted;
a power supply plate that is built in the mounting plate and electrostatically attracts the substrate to the mounting plate;
a plurality of protruding portions which internally includes an electrically conductive member respectively, is arranged on at least a central region and outer edge region of the mounting plate, and protrudes from the mounting surface; and
a plurality of elastic members which is embedded in the mounting plate to correspond to the plurality of protruding portions, supports the plurality of protruding portions while protruding the protruding portions from the mounting surface, and electrically connects the power supply plate and the electrically conductive members included in the plurality of protruding portions to each other.

12. The substrate processing apparatus according to claim 11, wherein
the substrate supporting apparatus further includes, below the mounting plate, an electric heating plate that heats the substrate.

13. The substrate processing apparatus according to claim 12, further comprising:
a first power supply that supplies power to the power supply plate;
a second power supply that supplies power to the electric heating plate; and
a control unit that controls the first and second power supplies, wherein
the control unit supplies power to the electric heating plate from the second power supply to preheat the substrate in a state where the substrate is mounted on the mounting plate, and thereafter, supplies power to the power supply plate from the first power supply to attract the substrate to the mounting plate.

14. The substrate processing apparatus according to claim 11, wherein
the plurality of protruding portions is arranged on the entire mounting surface of the mounting plate.

15. The substrate processing apparatus according to claim 14, wherein
the plurality of protruding portions
has a columnar shape, and is arranged on the mounting surface radially or in a grid shape, or
has an annular shapes, and is arranged on the mounting surface concentrically.

16. The substrate processing apparatus according to claim 11, wherein
the plurality of protruding portions includes:
a first protruding portion arranged on the central region; and
a second protruding portion which is arranged on the outer edge region and has a protrusion amount from the mounting surface, the protrusion amount being different from a protrusion amount of the first protruding portion.

17. The substrate processing apparatus according to claim 16, wherein
the protrusion amount of the first protruding portion is larger than the protrusion amount of the second protruding portion.

18. The substrate processing apparatus according to claim 16, wherein
the protrusion amount of the first protruding portion is smaller than the protrusion amount of the second protruding portion.

19. The substrate processing apparatus according to claim 11, wherein
the substrate supporting apparatus is also a lower electrode, and
the substrate processing apparatus further comprises:
an upper electrode that faces the substrate supporting apparatus; and
a high-frequency power supply that supplies power to at least either the lower electrode or the upper electrode to generate plasma.

20. The substrate processing apparatus according to claim 19, further comprising
a pump that vacuums an atmosphere in the processing container.
